(19) United States
(12) Patent Application Publication
(10) Pub. No.: US 2026/0052953 A1
(43) Pub. Date: Feb. 19, 2026

(54) WAFER BONDING WITH WARPAGE COMPENSATION

(71) Applicant: Applied Materials, Inc., Santa Clara, CA (US)

(72) Inventors: Siddarth KRISHNAN, Santa Clara, CA (US); Benjamin BRIGGS, Santa Clara, CA (US); Archana KUMAR, Mountain View, CA (US); Raghav SREENIVASAN, Fremont, CA (US); Niranjan R. KHASGIWALE, San Jose, CA (US)

(21) Appl. No.: 19/302,366

(22) Filed: Aug. 18, 2025

Related U.S. Application Data
(60) Provisional application No. 63/684,012, filed on Aug. 16, 2024.

(51) Int. Cl. H01L 21/66; H01L 23/00

(52) U.S. Cl. CPC H01L 22/12; H01L 24/03; H01L 24/05; H01L 24/80; H01L 2224/0384; H01L 2224/05624; H01L 2224/05647; H01L 2224/05655; H01L 2224/05684; H01L 2224/80895; H01L 2224/80896

(57) ABSTRACT

A method for bonding wafers is provided. More specifically, the method provides for forming a hybrid bond between wafers that compensates for warpage and offset on each of the wafers being bonded.

### CROSS-REFERENCE TO RELATED APPLICATIONS

This application claims the benefit of U.S. Provisional Application 63/684,012 filed on Aug. 16, 2024, which is herein incorporated by reference in its entirety.

### BACKGROUND

### Field

Embodiments of the present disclosure generally relate to semiconductor processing of semiconductor substrates.

### Description of the Related Art

In wafer-to-wafer bonding technology, various methods have been developed to bond two semiconductor wafers together to form stacked integrated circuits. The available bonding methods include direct metal bonding, hybrid bonding, fusion bonding, and the like. One problem in the art is that substrate processing techniques to form integrated circuits on conventional wafers can result in imperfections in the created pattern of one or more layers of the wafer. One issue encountered in any lithography process is substrate warpage or other defects that will affect the subsequent layers to be patterned over when forming the integrate circuits. Once a substrate is warped, i.e., the substrate has a curvature in two or three dimensions, the resultant location of the exposure of a photoresist applied to pattern the substrate will be shifted. Furthermore, if a warped substrate is used to carry a plurality of chip-die, each die on the warped substrate has local x-shift and y-shift, commonly known as die-shift. As resultant location of the exposure of the photoresist will be distorted and shifted, the corresponding pattern formed will also be shifted and disconnected. The magnitude and shape of warpage or defects may vary from layer to layer, and defects in one layer may add to defects in subsequent layers. Additionally, an underlying layer can include defects that will affect a layer to be patterned or bonded over the underlying layer.

One of the effects of substrate warpage is interfering with proper wafer-to-wafer bonding due to the shifting of certain features on the two wafers as a result of warpage or deformation of one or both of the wafers. For example, in some embodiments, alignment of the features between wafers is necessary for proper bonding in order to connect the circuitry of the two wafers critical for wafer performance. Shifting and misalignment of the features during bonding can result in the eventual production of a lower quality, or even a non-functional wafer or integrated circuit product.

Accordingly, what is needed in the art are improved methods for processing and bonding substrates.

### SUMMARY

In one embodiment, a method for bonding a first wafer and a second as described herein is provided. The method includes analyzing a top layer of a first wafer and a second wafer to determine warpage of each of the wafers, and generating a custom virtual mask for each of the first and second wafer to form a bonding layer for each of the first and second wafer. The bonding layer compensates for the determined warpage of the first and second wafer. The method also includes forming a patterned dielectric layer on the top layer of each of the first and second wafers using the generated custom virtual mask, forming a metal material layer on the patterned dielectric layers of each of the first and second wafers and performing a planarization process on the metal material layers to expose a plurality of metal bonding pads. The patterned dielectric layer and the exposed plurality of metal bond pads on the top layers form a bonding surface for each of the first and second wafers. The method continues with aligning the exposed plurality of metal bonding pads on the first wafer with the exposed plurality of metal bonding pads on the second wafer, and forming a hybrid bond between the first wafer and the second wafer by physically contacting the bonding surface of the first wafer with the bonding surface of the second wafer and bonding the first wafer and second wafer together.

In an embodiment, a method for forming a bonding layer on a wafer is provided. The method includes measuring locations of a plurality of features on a top layer of the wafer using a metrology tool, measuring for warpage and offset by the plurality of features using the metrology tool, and using the measured warpage and offset to generate design information for forming a patterned dielectric layer. The patterned dielectric layer compensates for the measured warpage of the wafer and any measured offset by the plurality of features. The method continues with forming a dielectric layer on the top layer of the wafer, patterning the dielectric layer using the design information to form a plurality of openings in the dielectric layer, disposing a metal material layer over the dielectric layer and in the plurality of openings, and performing a planarization process to remove excess portions of the metal material layer on the dielectric layer to expose a plurality of metal pads embedded in the dielectric layer. The exposed portions of the patterned dielectric layer and the plurality of metal pads provide a bonding surface for the wafer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic diagram of a processing system, according to certain embodiments;

FIG. 2 is a perspective view of a maskless lithography device, according to certain embodiments;

FIG. 3 is a flow diagram of a method for forming wafer-to-wafer hybrid bonds, according to certain embodiments;

FIG. 4 is a schematic cross-sectional view of an example feature offset between bonded wafers, according to certain embodiments; and

FIGS. 5A-5H are schematic cross-sectional views of forming a wafer-to-wafer hybrid bonds according to the method in FIG. 3, according to certain embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to processing and bonding of semiconductor substrates. More specifically, embodiments of the present disclosure relate to a system, and methods of using the system to perform a hybrid bonding process that compensates for wafer warpage when bonding two wafers together. Conventionally, hybrid bonding includes forming and bonding metal pads of two wafers to each other through direct metal-to-metal bonding, and bonding an oxide surface of one of the two wafers to an oxide surface or a silicon surface of the other wafer. In an embodiments, the present disclosure provides for hybrid bonding conductive metal pads embedded in a patterned photo-imageable polymer dielectric layer formed on the bonding surfaces of each of the wafers. The patterned photo-imageable polymer dielectric layer compensates for measured substrate warpage to ensure proper bonding of the two wafers.

In some embodiments, a top layer of each of the wafers includes a plurality of features (e.g., bonding surface of vias, conductive traces, interconnection structures, etc.) coupled to or in contact with electrical circuitry within each of the wafers. In some embodiments, such plurality of features of each of the wafers must be aligned and electrically connected for proper bonding to form stacked integrated circuits. Since wafers often include a plurality of layers (e.g., in some embodiments, up to sixty four (64) layers) fabricated over one another to form integrated circuits and dies, the various processing operations performed to form each of the plurality of layers may cause wafer warpage or substrate deformation. Such warpage or deformation may in turn cause pattern defects or feature offsets in which the actual location of each the features as actually formed on the wafer is different and/or offset from the designed location that the features were expected to and would otherwise have been formed on if substrate warpage had not occurred.

To compensate for and ensure proper alignment during bonding, the method of the present disclosure utilizes a metrology tool to analyze warpage and check whether the plurality of features on the top layers of the wafers were offset (e.g., formed on a shifted location due to warpage) and therefore misaligned (as compared to the designed feature location based on the original mask/pattern design file used for forming each of the features in the top layers). Detected defects/offsets/shifts resulting from distortion caused by warpage in one or both of the wafers may then be used for assessing whether adjustments or offsets need to be made in order to electrically connect the plurality of features of the wafers during bonding. In some embodiments, if compensation of pattern defects and/or offset of features on the top layers of at least one of the wafers is required for proper bonding, a new mask design file that compensates for the detected pattern defect is generated for forming a bonding layer on the top layers of each of the wafers to be bonded. The new mask design file may be used to pattern a new bonding layer to be formed over the top layers of each of the wafers using a maskless lithography technique. Maskless lithography techniques include electron beam lithography, optical lithography, direct laser writing, focused ion beam lithography, probe-tip contact lithography, and the like. The patterned bonding layer on the warped substrate in turn may compensate for warpage and any associated shifts to provide for electrically connecting any shifted features when the substrate is bonded.

For example, where a substrate is warped and at least one feature is determined to have been shifted during the lithography process resulting in an offset, the system and methods herein allow the new mask design file to be written to a polymer layer to be disposed on the top layer of the warped wafer to form a new bonding layer that compensates for the warpage and offset. The patterned polymer layer includes a respective metal connection pad in contact with each of the plurality of features for compensating for any offset and subsequent use in forming a hybrid bond between the two wafers. The method disclosed herein accordingly also provides for compensating for misalignments caused by substrate warpage to form electrically connected conductive structures between the bonded wafers.

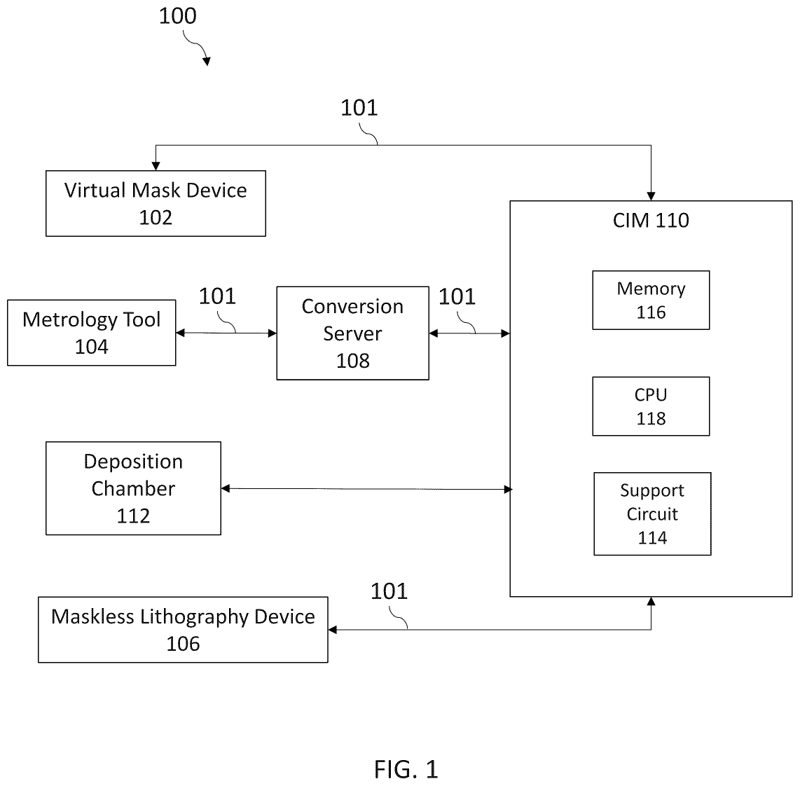

FIG. 1 is a schematic view of a processing system 100 for analyzing and bonding two substrates, according to certain embodiments. As used herein, a “substrate” refers to any substrate, material surface formed on a substrate, wafer, packaged wafer, film stack or the like upon which processing or bonding is performed during a fabrication process.

As shown, the processing system 100 includes, but is not limited to, a virtual mask device 102, a metrology tool 104, a maskless lithography device 106, a conversion server 108, a computer-integrated manufacturing (CIM) system 110, a deposition chamber 112, and communication links 101. Each of the virtual mask device 102, the metrology tool 104 and the maskless lithography device 106 may be communicatively connected to the CIM system 110 that controls operations of the virtual mask device 102, the metrology tool 104, the maskless lithography device 106, and the conversion server 108. The wafers of processing system 100 may be operable to be connected to the CIM system 110 as well as to each other via the communication links 101. The processing system 100 can be located in the same area or production facility, or each of the wafers of processing system 100 can be located in different areas.

Each of the wafers of processing system 100 may be indexed with operations for performing the methods described herein. Each of the virtual mask device 102, the metrology tool 104, the maskless lithography device 106, the conversion server 108, and the CIM system 110 include an on-board processor and memory, where the memory is configured to store instructions corresponding to any portion of the methods described below. The communication links 101 may include at least one of wired connections, wireless connections, satellite connections, and the like. The communications links 101 include sending and receiving files to store data, according to embodiments further described herein. The communications links 101 can include temporarily or permanently storing files or data in the cloud, before transferring or copying the files or data to a lithography environment wafer.

In one embodiment, which can be combined with other embodiments described herein, the maskless lithography device 106, the deposition chamber 112. and the metrology tool 104 are connected by a transfer system. The transfer system is operable to transfer a substrate between the maskless lithography device 106, the deposition chamber 112, and the metrology tool 104. In one embodiment, which can be combined with other embodiments described herein, the transfer system can include robots or other equipment connectable to the CIM system 110 operable to transfer patterned substrates. In one embodiment, which can be combined with other embodiments described herein, the transfer system is physically operable by the user.

The CIM system 110 includes a central processing unit (CPU) 118, support circuits 114 and a memory 116. The CPU 118 can be one of any form of computer processor that can be used in an industrial setting for controlling the lithography environment wafers. The memory 116 is coupled to the CPU 118. The memory 116 can be one or more of readily available memory, such as random access memory (RAM), read only memory (ROM), floppy disk, hard disk, or any other form of digital storage, local or remote. The support circuits 114 are coupled to the CPU 118 for supporting the processor in a conventional manner. These circuits include cache, power supplies, clock circuits, input/output circuitry, subsystems, and the like. The CIM system 110 can include the CPU 118 that is coupled to input/output (I/O) wafers found in the support circuits 114 and the memory 116. The CIM system 110 is operable to receive a GDS file and transfer the GDS file to the maskless lithography device 106 via the communication links 101. The CIM system 110 is operable to receive a virtual mask file and transfer the virtual mask file to the maskless lithography device 106 via the communication links 101.

The memory 116 can include one or more software applications, such as a controlling software program. The memory 116 can also include stored media data that is used by the CPU 118 to perform the methods described herein. The CPU 118 can be a hardware unit or combination of hardware units capable of executing software applications and processing data. In some configurations, the CPU 118 includes a central processing unit (CPU), a digital signal processor (DSP), an application-specific integrated circuit (ASIC), and/or a combination of such units. The CPU 118 is generally configured to execute the one or more software applications and process the stored media data, which can be each included within the memory 116. The CIM system 110 controls the transfer of data and files to and from the various lithography environment wafers. In some embodiments, the memory 116 is configured to store instructions corresponding to any operation of the methods described herein.

In an embodiment, the virtual mask device 102 is operable to receive a design file. The design file determines which tasks are to be performed on the substrates. The design file (or computer instructions), which may be referred to as an imaging design file or a graphic design system (GDS) file, is converted into the virtual mask file by the virtual mask device 102. The virtual mask file includes mask pattern data and is a digital representation of the design to be printed by the maskless lithography device 106. The virtual mask file may be sent through the CIM system 110 to the maskless lithography device 106 via the communication links 101. In one embodiment, which can be combined with other embodiments described herein, the virtual mask file may be sent directly to the maskless lithography device 106. The virtual mask file may be stored in the maskless lithography device 106. In another embodiment, which can be combined with other embodiments described herein, the virtual mask file includes a layered file. For example, the virtual mask file can include multiple layers of the design that correspond to the multiple layers to be patterned into the photoresist.

The metrology tool 104 is operable to analyze and measure features on a substrate. In an embodiment, the metrology tool 104 may be used for detecting warpage, defects, and shifts on the substrate. In one embodiment, which can be combined with other embodiments described herein, the metrology tool 104 can detect warpage of the substrate. In an embodiment, the metrology tool 104 can be used to detect effects caused by defects (e.g., warpage) of a substrate including determining shifts of features due to substrate warpage. For example, the metrology tool 104 may be used for measuring the actual locations of features formed on the warped substrate. When compared with the designed locations of the measured features from the design files used for forming the features, the actual locations of the features measured by the metrology tool 104 provides for determine whether a shift of the measured features on the substrate occurred. In another embodiment, which can be combined with other embodiments described herein, the metrology tool 104 can detect shifts of features on the substrate. In some embodiments, the metrology tool 104 can detect defects in each layer patterned on the substrates. In some embodiments, the metrology tool 104 can detect defects in a non-patterned substrate.

The metrology tool 104 is in communication with the conversion server 108 via the communication links 101. The metrology tool 104 may be configured to notify the conversion server 108 of the detection of any defects or shifts on the substrate due to substrate warpage. In one embodiment, which can be combined with other embodiments described herein, the conversion server 108 can run a conversion script to generate instructions for forming a virtual mask for a bonding layer that compensates for the defects and shifts detected on the analyzed substrate.

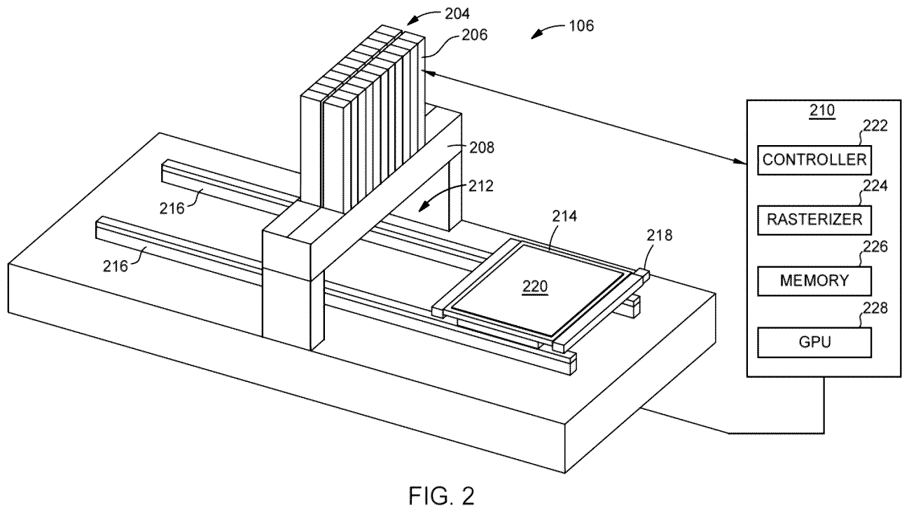

FIG. 2 is a perspective view of a maskless lithography device 106, such as a digital lithography system, that may benefit from embodiments described herein. The maskless lithography device 106 includes a stage 214 and a processing unit 204. The stage 214 is supported by a pair of tracks 216. A substrate 220 is supported by the stage 214. The stage 214 is operable to move along the pair of tracks 216. An encoder 218 is coupled to the stage 214 in order to provide information of the location of the stage 214 to a lithography server 210. The lithography server 210 includes, but is not limited to a controller 222, a rasterizer 224, a memory 226, and a GPU 228.

The controller 222 is generally designed to facilitate the control and automation of the processing techniques described herein. The controller 222 may be coupled to or in communication with the processing unit 204, the stage 214, and the encoder 218. The processing unit 204 and the encoder 218 may provide information to the controller 222 regarding the substrate processing and the substrate aligning. For example, the processing unit 204 may provide information to the controller 222 to alert the controller 222 that substrate processing has been completed. The controller 222 facilitates the control and automation of a maskless lithography process, such as a digital lithography process based on the virtual mask file provided to the lithography server 210. The virtual mask file is provided to the lithography server 210 from the CIM system 110 via the communication links 101. The virtual mask file is created by the virtual mask device 102 using the design file (GDS file). The design file includes a mask pattern data.

The controller 222 retrieves and executes programing data stored in the memory 226 and coordinates operations of other system components. Similarly, the controller 222 stores and retrieves application data residing in the memory 226. The controller 222 may be one or more central processing units (CPUs). Alternatively, or additionally, the controller 222 may be one or more application specific software programs.

The memory 226 may store instructions and logic to be executed by the controller 222. Further, the memory 226 may be one or more of a random access memory (RAM) and a non-volatile memory (NVM). The NVM may be a hard disk, a network attached storage (NAS), and a removable storage wafer, among others.

The substrate 220 comprises any suitable material, for example, glass, which can used as part of a flat panel display. In other embodiments, the substrate 220 could be a wafer used in advanced packaging (AP) or similar applications in semiconductor manufacturing. The substrate 220 has a film layer to be patterned thereon, such as by pattern etching thereof, and a may have photoresist formed on the film layer to be patterned, which is sensitive to electromagnetic radiation, for example UV or deep UV “light”. In an embodiment, the film layer to be patterned comprises a bonding layer configured to be patterned to compensate for warpage and offsets in the underlying layers below.

A positive photoresist includes portions of the photoresist, when exposed to radiation, are respectively soluble to a photoresist developer applied to the photoresist after the pattern is written into the photoresist using the electromagnetic radiation. A negative photoresist includes portions of the photoresist, when exposed to radiation, will be respectively insoluble to photoresist developer applied to the photoresist after the pattern is written into the photoresist using the electromagnetic radiation. The chemical composition of the photoresist determines whether the photoresist is a positive photoresist or negative photoresist. Examples of photoresists include, but are not limited to, at least one of diazonaphthoquinone, a phenol formaldehyde resin, poly(methyl methacrylate), poly(methyl glutarimide), and SU-8. After exposure of the photoresist to the electromagnetic radiation, the resist is developed to leave a patterned photoresist on the underlying film layer. Then, using the patterned photoresist, the underlying thin film is pattern etched through the openings in the photoresist to form a portion of the electronic circuitry of the display panel or advanced packaging wafer.

In another embodiment, the film layer on the substrate 220 to be patterned thereon may comprise a photo imageable dielectric (PID) polymer material that may be directly patterned by the maskless lithography device 106. The PID polymer material may similarly be either a positive PID polymer material that becomes respectively soluble to a developer when exposed to a radiation, or a negative PID polymer material that becomes respectively soluble to a developer when exposed to a radiation.

The processing unit 204 is supported by the support 208 such that the processing unit 204 straddles the pair of tracks 216. The support 208 provides an opening 212 for the pair of tracks 216 and the stage 214 to pass under the processing unit 204. The processing unit 204 is a pattern generator configured to receive the virtual mask file from the lithography server 210 and expose the photoresist in the maskless lithography process using one or more image projection systems 206 operable to project write beams of electromagnetic radiation to the substrate 220. The pattern generated by the processing unit 204 is projected by the image projection systems 206 to expose the photoresist of the substrate 220 to the mask pattern that is written into the photoresist.

In one embodiment, which can be combined with other embodiments described herein, each image projection system 206 includes a spatial light modulator to modulate the incoming light to create the desired image. Each spatial light modulator includes a plurality of electrically addressable elements that may be controlled individually. Each electrically addressable element may be in an “ON” position or an “OFF” position based on the virtual mask file provided to the maskless lithography device 106. When the light reaches the spatial light modulator, the electrically addressable elements that are in the “ON” position project a plurality of write beams to a projection lens (not shown). The projection lens then projects the write beams to the substrate 220. The electrically addressable elements include, but are not limited to, digital micro-mirrors, liquid crystal displays (LCDs), liquid crystal over silicon (LCoS) wafers, ferroelectric liquid crystal on silicon (FLCoS) wafers, microshutters, microLEDs, VCSELs, liquid crystal displays (LCDs), or any solid state emitter of electromagnetic radiation.

The rasterizer 224, in some embodiments comprises one or more rasterizer computation engines and in embodiments, one or more spatial light modulator (SLM) arrays. In alternate embodiments, SLM arrays may comprise one or more digital micro-mirror (DMD) wafers, microLED, VCSEL, and/or LCD arrays, or other type of spatial light modulators. The rasterizer 224 may include a rasterizer computation engine which includes one or more field programmable gate arrays (FPGAs), graphics processing units (GPUs), a combination of FPGAs and GPUs, or other processing hard/firmware capable of converting data in an image format to a format understandable by a DMD.

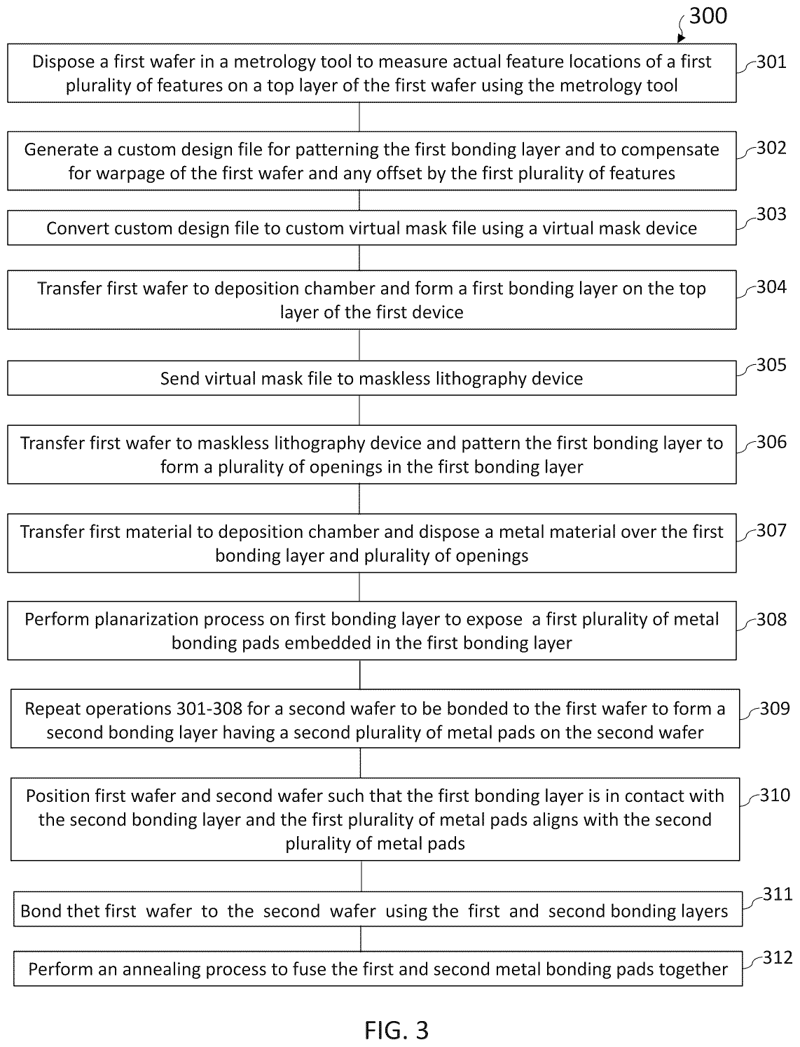

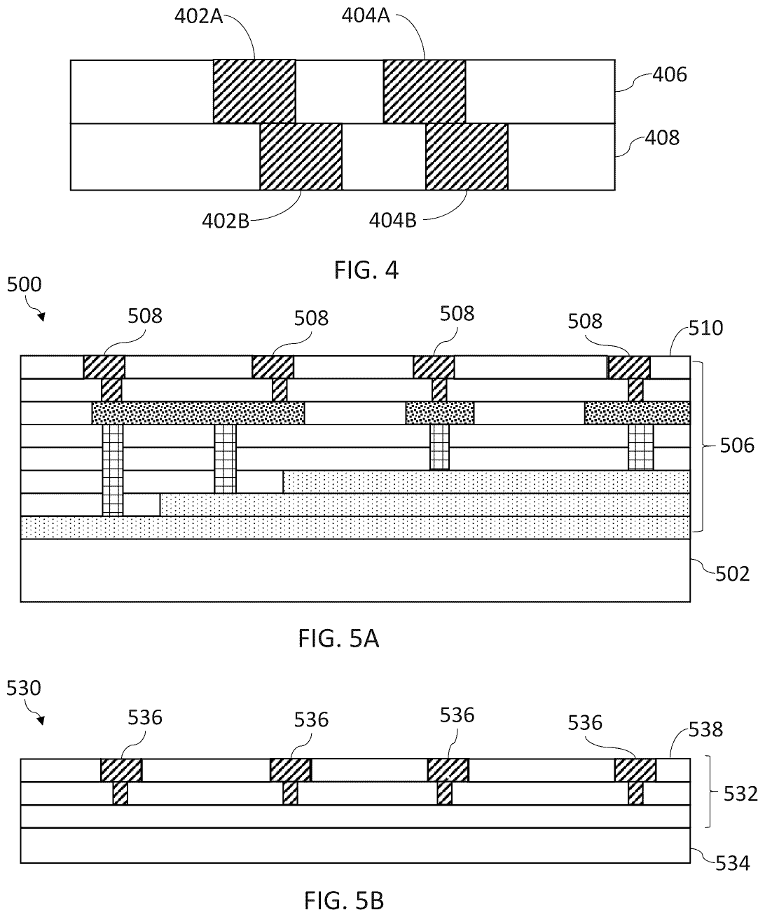

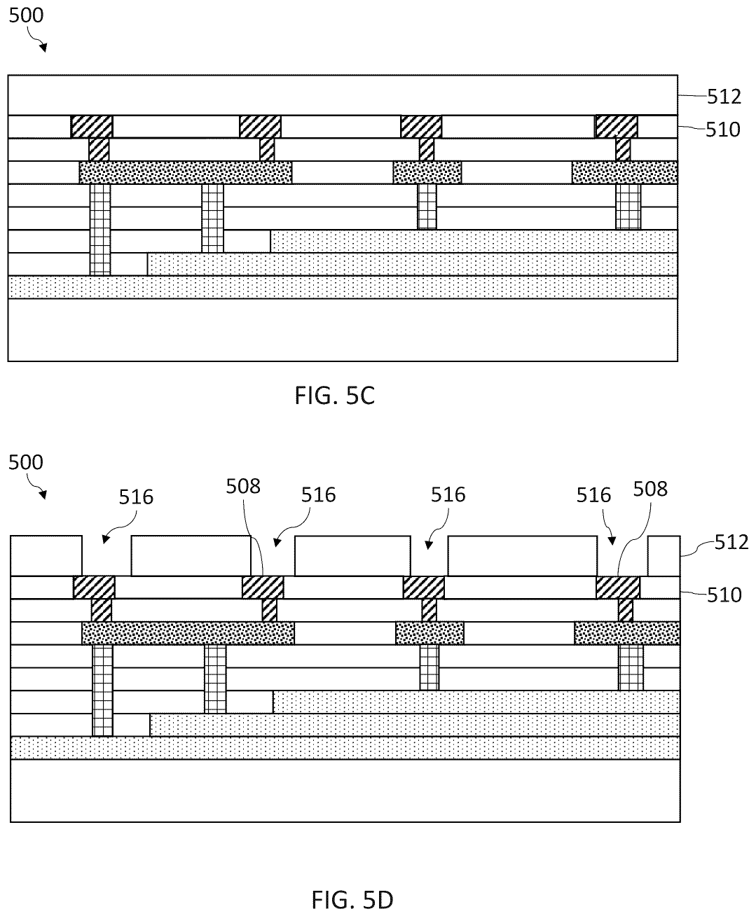

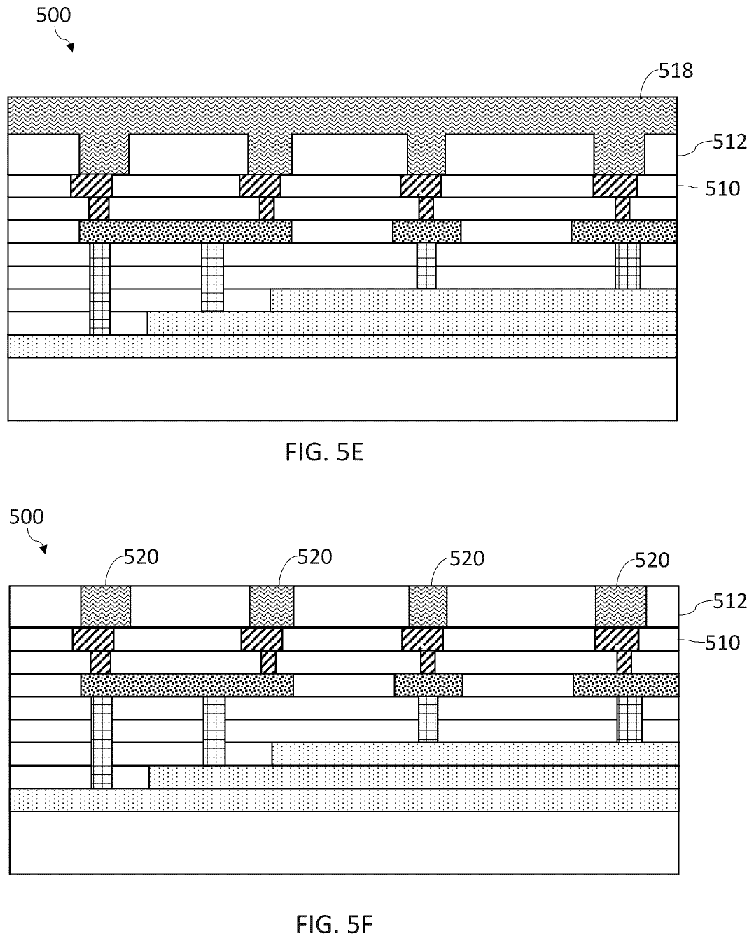

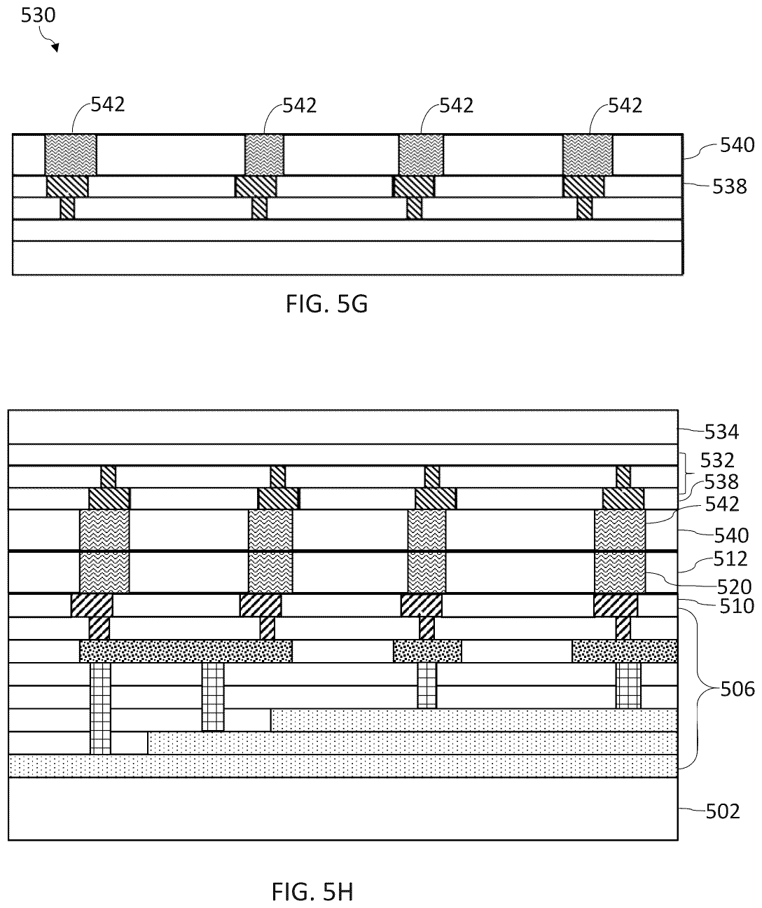

FIG. 3 is a flow chart of a method 300 for bonding a first wafer 500 and a second wafer 530, as shown in FIGS. 5A-5, using the processing system 100 depicted in FIG. 1, according to certain embodiments. FIG. 3 provides for proper wafer-to-wafer bonding so as to avoid misalignments of certain conducting features between bonded wafers, such as the misalignment of features 402A-B and features 404A-B when a first layer 406 and a second layer 408 are bonded, as shown in FIG. 4.

Method 300 begins at operation 301 in which the first wafer 500, as shown in FIG. 5A, is disposed in a metrology tool, such as the metrology tool 104, for analyzing and measuring the first wafer 500. In an embodiment, the first wafer 500 may be a wafer comprising a plurality of layers formed on a substrate 502, for example, a semiconductor substrate. The first wafer 500 may include a plurality of layers, devices and/or features formed on the substrate 502, such as transistors, metal lines, vias, shallow trench isolation (STI), interconnects, vias between adjacent metal layers, inter-metal dielectric layers (ILD), pre-metal dielectrics (PMD), passivation layers, patterning applications, and the like. In other embodiments, the first wafer 500 may be a packaged wafer, an interposer wafer, film stacks, or the like. In the example shown, the first wafer 500 includes a plurality of metal lines, vias, and interconnects formed in a plurality of layers 506, including a plurality of features 508 formed in a top layer 510 on the substrate 502. In an embodiment, the plurality of features 508 may be a plurality vias coupled to or in contact with electrical circuitry within the first wafer 500.

Operation 301 includes using the metrology tool 104 to analyze the first wafer 500 to check for defects in the first wafer 500 such as warpage, offset, feature shifts, and other defects that may affect proper bonding of the first wafer 500. For example, FIG. 4 shows an example wafer-to-wafer bonding in which an offset of features 402A and 404A in the first layer 406 causes a misalignment with features 402B and 404B in second layer 408 when the first and second layers 406, 408 are bonded.

In an embodiment, prior to analyzing the first wafer 500 in operation 301, a GDS file or a corresponding virtual mask file for patterning the first wafer 500 may be sent to the metrology tool 104 to provide patterning data corresponding to the top layer 510, including the designed locations of each of the plurality of features 508 in the top layer 510. In an embodiment, the metrology tool 104 measures the actual locations of the features 508 in the top layer 510 for comparison with the designed locations of the features 508 to determine any offset or shifts in the locations of the features 508 between the designed locations and as actually formed on the first wafer 500. In an embodiment, the measurements are in the form of Cartesian coordinates. In another embodiment, the measurements are in the form of vectors. In yet another embodiment, the measurements are in the form of a distance and angle from a reference point.

Based on the measured offset by the features 508 (if any), an assessment may then be made as to whether a bonding layer for compensating for any offset is necessary. For example, the extent of the shift of any of the features 508 may be assessed against a predetermined offset threshold to determine whether compensation when bonding the first wafer 500 is to be performed. In an embodiment, substrate warpage may cause one or more of the features 508 to shift between about 0.5 and about 2 microns from the designed locations. In an embodiments, the assessment on whether compensation is needed may be performed by the metrology tool 104 or the conversion server 108. If compensation for offset is needed, the metrology tool 104 communicates the data corresponding to the detected warpage, shifts, and/or offset to the conversion server 108.

In operation 302, using the data received from the metrology tool 104, the conversion server 108 may then generate a new custom design file (e.g., GDS file) for patterning a bonding layer to be formed on the top layer 510, wherein the bonding layer compensates for the detected warpage and feature offset in the first wafer 500 in operation 301. The bonding layer to be formed takes the detected warpage into account when patterning the bonding layer to provide for forming metal pads in the bonding layer that compensate for the offset by the features 508.

In operation 303, the new custom design file may be sent to the virtual mask device 102 for conversion to a corresponding new virtual mask file. The new corresponding virtual mask file is a digital representation of the pattern to be written in the bonding layer for forming a bonding surface having a plurality of metal pads that compensates for the detected warpage and offsets in the first wafer 500. In operation 304, the new virtual mask file may then be sent to the maskless lithography device 106. In an embodiment, the virtual mask file may be sent through the CIM system 110 to the maskless lithography device 106 via the communication links 101. In another embodiment, the virtual mask file may be sent to the maskless lithography device 106 directly. The virtual mask file is stored in the maskless lithography device 106 for printing.

In another embodiment, generating the new GDS file or corresponding new virtual mask file for the bonding layer may alternatively comprise editing the GDS file or corresponding virtual mask file for patterning the top layer 510 previously used by the metrology tool 104 when analyzing the first wafer 500 in operation 301.

In operation 305, the first wafer 500 is transferred from the metrology tool 104 to the deposition chamber 112 and a first bonding layer 512 512 is deposited on the top layer 510, as shown in FIG. 5C. In an embodiment, the first bonding layer 512 includes a PID polymer material that may be patterned directly by the maskless lithography device 106. In other embodiments, the first bonding layer 512 may be a dielectric material such as silicon oxynitride (SiON), silicon oxide (SiO₂), silicon nitride (SiN), or the like. In an embodiment, the first bonding layer 512 may be deposited by one or more physical vapor deposition (PVD), chemical vapor deposition (CVD), plasma-enhanced (PECVD), flowable CVD (FCVD), atomic layer deposition (ALD), and spin-on processes.

In operation 306, the first wafer 500 is transferred from the deposition chamber 112 to the maskless lithography device 106 and patterned by the maskless lithography device 106. The maskless lithography device 106 utilizes the new virtual mask file received from the virtual mask device 102 in operation 304 to pattern the first bonding layer 512 so as to compensate for the warpage and offset measured in operation 301. Once the first bonding layer 512 is patterned and cured, a plurality of openings 516 is formed in the first bonding layer 512, as shown in FIG. 5D. Operation 306 includes etching through the first bonding layer 512 with the maskless lithography device 106 such that the underlying features 508 are exposed through the plurality of openings 516. The location and size of the plurality of openings 516 are etched so as to provide for forming bonding pads in the first bonding layer 512 that are positioned to compensate for the offset by the features 508 measured in operation 301.

In certain embodiments, the maskless lithography device 106 may pattern the first bonding layer 512 using electron beam lithography, optical lithography, direct laser writing, focused ion beam lithography, probe-tip contact lithography, and the like. In an embodiment, the first bonding layer 512 comprises a PID polymer material and the maskless lithography device 106 patterns the first bonding layer 512 directly. In another embodiment, a photoresist is formed and patterned over the first bonding layer 512 to aid in the patterning of the first bonding layer 512.

At operation 307, the first wafer 500 is transferred back to the deposition chamber 112 and a metal material layer 518 is disposed over the first bonding layer 512 including filling the plurality of openings 516, as shown in FIG. 5E. In certain embodiments, the metal material layer 518 may be disposed using atomic layered deposition (ALD), physical vapor deposition (PVD), or an electrochemical deposition (ECD)/electroplating (ECP) process. The metal material layer 518 may be any conductive interconnect material, such as copper (Cu), aluminum (Al), nickel, tungsten, alloys thereof, or other suitable materials. In another embodiment, the first wafer 500 may be transferred to a different process chamber for forming the metal material layer 518 on the first wafer 500.

At operation 308, a planarization process, such as a chemical mechanical polish (CMP) is performed to remove excess portions of the metal material layer 518 on the first bonding layer 512 to expose a plurality of metal bonding pads 520 embedded within the first bonding layer 512, as shown in FIG. 5F. The planarizing process also forms a bonding surface on the first wafer 500. In an embodiment, each of the metal bonding pads 520 may comprise a length of about 1 micron and a width in a range from about 1 micron to about 3 micron. In an embodiment, the metal bonding pads 520 may be sized as needed to compensate for the offset by the corresponding plurality of features 508 in the underlying layer below the first bonding layer 512.

At operation 309, prior operations 301-308 are repeated for the second wafer 530 depicted in FIG. 5B. In an embodiment, the second wafer 530 may be similar to the first wafer 500 comprising a plurality of layers, features, and/or wafers formed on a semiconductor substrate. In another embodiment, the second wafer 530 may be an incoming wafer, a packaged wafer, an interposer wafer, film stacks, or the like. In the example shown, the second wafer 530 comprises a plurality of layers 532 formed on a substrate 534 and a plurality of features 536 formed in a top layer 538 of the second wafer 530. Each of the plurality of features 536 is intended to be conductively connected with the plurality of features 508 when the first wafer 500 is bonded to the second wafer 530.

In an embodiment, as the first bonding layer 512 and the metal bonding pads 520 formed on the first wafer 500 are to be utilized to form a hybrid bond between the first wafer 500 and the second wafer 530, a corresponding second bonding layer is similarly formed over the top layer 538 of the second wafer 530. In an embodiment, even if no offset is detected in the plurality of features 536 in the top layer 538 of the second wafer 530, operations 301-308 may still be performed to form the second bonding layer on the second wafer 530.

The results of operation 309 in which operations 301-308 are repeated, is shown in FIG. 5G in which a second bonding layer 540 having a plurality of metal bonding pads 542 is formed over the top layer 538 of the second wafer 530. As with the first bonding layer 512 formed for the first wafer 500, in an embodiment, if warpage and offset by the plurality of features 536 was detected in the second device 530, the second bonding layer 540 similarly compensates for any such warpage and offset by the plurality of features 536 to provide for proper bonding with the first wafer 500.

At operation 310, to bond the first wafer 500 to the second wafer 530, the first wafer 500 and the second wafer 500 are positioned such that the first bonding layer 512 and the second bonding layer 540 are face to face, and the plurality of metal bonding pads 520, 542 on the two wafers 500, 530 are each respectively aligned, as shown in FIG. 5H.

Once aligned, operation 311 proceeds with performing a hybrid bonding process by applying a thermo-compressive force so as to bond the first and second wafers 500, 530 together using the first and second bonding layers 512, 540 and the metal bonding pads 520, 542 respectively embedded therein. In an embodiment, the hybrid bond formed includes forming bonds between the PID polymer material of the first and second bonding layers 512, 540 and the metal bonding pads 520, 542 of the first and second wafers 500,530. In an embodiment, the bonding process can be performed at atmospheric pressure.

In operation 312, a post bond annealing process is performed to fuse the metal bonding pads 520, 542 together. When the bonding layers 512, 540 are bonded, a hybrid bond is formed in which the bonding layers 512, 540 are mechanically bonded together, and the metal bonding pads 520, 542 form metal cores extending between the two wafers 500, 530 so as to electrically connect each of the plurality of features 508 in the first wafer 500 with a respective feature 536 in the second wafer 530.

The systems and methods described herein provide for forming hybrid bonds that compensate for wafer warpage so as to ensure proper alignment when bonded. Specifically, the systems and methods provide for forming custom bonding layers on each wafer having a plurality of metal bonding pads integrated in a photo imageable polymer dielectric (PID) bonding layer. As misalignments and offsets of certain features during bonding can result in the eventual production of a lower quality, or even a non-functional wafer or integrated circuit product, ensuring proper alignment during wafer-to-wafer bonding can provide for minimizing yield loss due to warpage and associated defects.

Embodiments of the disclosure have been described above with reference to specific embodiments and numerous specific details are set forth to provide a more thorough understanding of the present disclosure. Persons skilled in the art, however, will understand that various modifications and changes may be made thereto without departing from the broader spirit and scope of the disclosure. The foregoing description and drawings are, accordingly, to be regarded in an illustrative rather than a restrictive sense.

While the foregoing is directed to embodiments of the present disclosure, other and further embodiments of the disclosure may be devised without departing from the basic scope thereof, and the scope thereof is determined by the claims that follow.

What is claimed is:

1. A method for bonding wafers, comprising:
analyzing a top layer of a first wafer and a second wafer to determine warpage of each of the wafers;
generating a custom virtual mask for each of the first and second wafer to form a bonding layer for each wafer that compensates for the determined warpage;
forming a patterned dielectric layer on the top layer of each of the first and second wafers using the custom virtual mask;
forming a metal material layer on the patterned dielectric layers of each of the first and second wafers;
exposing through the metal material layer a first plurality of metal bonding pads on the first wafer and a second plurality of metal bonding pads on the second wafer to form a bonding surface on each of the first and second wafer;
aligning the exposed plurality of metal bonding pads on the first wafer with the exposed plurality of metal bonding pads on the second wafer;
forming a hybrid bond between the first wafer and the second wafer by physically contacting the bonding surface of the first wafer with the bonding surface of the second wafer and bonding the first wafer and second wafer together.

2. The method of claim 1, wherein determining warpage of at least two wafers further comprises measuring and determining offset of a plurality of features in each of the top layers of the at least two wafers.

3. The method of claim 1, wherein forming the hybrid bond comprises bonding the patterned dielectric layer on the first wafer and the patterned dielectric layer on the second wafer together, and bonding the first plurality of metal bond pads aligned with the second plurality of metal bonding pads together.

4. The method of claim 3, wherein the first plurality of metal pads is bonded with the second plurality of metal pads using a thermal anneal process.

5. The method of claim 3, wherein the patterned dielectric layer of the first wafer is bonded with the patterned dielectric layer of the second wafer using thermo-compression.

6. The method of claim 1, wherein the metal material layer comprises copper (Cu), aluminum (AI), nickel (Ni), tungsten (W), alloys thereof, or other suitable conductive metal materials.

7. A method for forming a bonding layer on a wafer, comprising:
measuring locations of a plurality of features on a top layer of the wafer using a metrology tool;
measuring for warpage and offset by the plurality of features using the metrology tool;
using the warpage measured and offset to generate design information for patterning a dielectric layer, the design information enabling compensation for warpage of the wafer or any offset by the plurality of features;
forming a dielectric layer on the top layer of the wafer;
patterning the dielectric layer using the design information to form a plurality of openings in the dielectric layer;
disposing a metal material layer over the dielectric layer and in the plurality of openings; and
performing a planarization process to remove excess portions of the metal material layer on the dielectric layer to expose a plurality of metal pads embedded in the dielectric layer and form a bonding surface on the wafer.

8. The method of claim 7, further comprising sending design information to the metrology tool for patterning the top layer of the wafer prior to measuring for offset.

9. The method of claim 8, wherein measuring for offset by the plurality of features comprises comparing measured locations of each of the plurality of features with corresponding design locations for each of the plurality of features based on design information used for patterning the top layer.

10. The method of claim 7, wherein the dielectric layer is a photo imageable dielectric polymer material, and patterning the dielectric layer comprises directly patterning the dielectric layer using a maskless lithography device.

11. A method for bonding wafers, comprising:
forming a first bonding layer on a top layer of a first wafer, wherein forming the first bonding layer comprises:
measuring locations of a first plurality of features on the top layer of the first wafer using a metrology tool;
measuring for warpage and offset by the first plurality of features using the metrology tool;
generating a custom design file for patterning the first bonding layer and to compensate for warpage of the first wafer or any offset by the first plurality of features;
forming a dielectric layer on the top layer of the first wafer;
patterning the dielectric layer using the custom design file to form a plurality of openings in the dielectric layer;
disposing a metal material layer over the dielectric layer and in the plurality of openings; and
performing a planarization process to remove excess portions of the metal material layer to expose a first plurality of metal pads embedded in the dielectric layer;
forming a second bonding layer on a second top layer of a second wafer, the second bonding layer comprising a second plurality of metal pads embedded in a second dielectric layer formed on the second top layer of the second wafer;
positioning the first wafer with the second wafer such that the first bonding layer is in contact with the second bonding layer, and the first plurality of metal pads aligns with the second plurality of metal pads; and
bonding the first wafer to the second wafer using the first and second bonding layers, wherein the first plurality of metal pads of the first bonding layer is bonded to the second plurality of metal pads of the second bonding layer.

12. The method of claim 11, further comprising sending to the metrology tool an original design file used for patterning the top layer of the first wafer prior to measuring for offset.

13. The method of claim 12, wherein measuring for offset by the first plurality of features comprises comparing measurements of actual feature locations of each of the first plurality of features with corresponding designed feature locations of each of the first plurality of features obtained from the original design file.

14. The method of claim 11, further comprising converting the custom design file to a custom virtual mask file using a virtual mask device and sending the custom virtual mask file to a maskless lithography device prior to patterning the dielectric layer, and wherein the dielectric layer is patterned with the maskless lithography device.

15. The method of claim 14, further comprising transferring the first wafer from the maskless lithography device and to a deposition chamber after patterning the dielectric layer and prior to disposing the metal material layer over the dielectric layer.

16. The method of claim 11, wherein the dielectric layer comprises a photo imageable dielectric polymer material, and patterning the dielectric layer comprises directly patterning the dielectric layer.

17. The method of claim 11, wherein the second bonding layer is configured to compensate for warpage of the second wafer or any offset by a second plurality of features in the top layer of the second wafer.

18. The method of claim 11, wherein the first plurality of features in the top layer of the first wafer is coupled to or in contact with electrical circuitry within the first wafer.

19. The method of claim 11, further comprising transferring the first wafer from the metrology tool to a deposition chamber after measuring actual feature locations for the first wafer.

20. The method of claim 11, wherein forming the second bonding layer comprises:
measuring actual feature locations of a second plurality of features on the second top layer of the second wafer using the metrology tool;
measuring for warpage and offset by the second plurality of features using the metrology tool;
generating a second custom design file for patterning the second dielectric layer to compensate for warpage of the second wafer or any offset by the second plurality of features;
forming the second dielectric layer on the top layer of the first wafer;
patterning the second dielectric layer using the second custom design file to form a second plurality of openings in the second dielectric layer;
disposing a second metal material layer over the second dielectric layer and in the second plurality of openings; and
performing a second planarization process to remove excess portions of the second metal material layer to expose the second plurality of metal pads embedded in the second dielectric layer.
